(19) United States
(12) Patent Application Publication
(10) Pub. No.: US 2006/0062330 A1
(43) Pub. Date: Mar. 23, 2006

(54) Modulation method using hard decision for quadrature amplitude modualtion and an apparatus thereof

(76) Inventors: Hong-Seok Seo, Seongnam (KR); Tae-Hoon Kim, Seoul (KR)

Correspondence Address: RABIN & Berdo, PC, 1101 14TH STREET, NW, SUITE 500, WASHINGTON, DC, 20005, US

(21) Appl. No.: 10/536,755

(22) PCT Filed: Jun. 25, 2003
(86) PCT No.: PCT/KR03/01246

§ 371 Date: May 27, 2005

(30) Foreign Application Priority Data
Jun. 23, 2003 (KR) 10-2003-0040901

(51) Int. Cl. H03D 1/24

(52) U.S. Cl. 375/320

(57) ABSTRACT

The invention relates to a hard decision demodulation of a square type of a quadrature amplitude modulation signal, in particular, to a hard decision demodulation method and apparatus capable of performing fast and accurate demodulation, by demodulating a received signal in bit unit when demodulating it. In a hard decision demodulation method of a square type of quadrature amplitude modulation signal, by determining in bit unit, not in symbol unit a corresponding output value from a quadrature phase component value and an in-phase component value, it is possible to develop a more useful demodulation technique and to give a secondary function by independently processing each bit, according to the demodulation of bit unit. Further, the invention can be constituted of merely a comparison circuit without having arithmetic in demodulation process, and therefore, can enhance flexibility of actual configuration and processing speed.

### TECHNICAL FIELD

The invention relates to a hard decision demodulation, in particular, to a hard decision demodulation method capable of performing fast and accurate demodulation, by demodulating a received signal in bit unit when demodulating it.

### BACKGROUND ART

As shown in FIG. 1, an original source is carried on a carrier signal by a modulator and then is sent via a transmission medium. A demodulator at a receive portion removes the carrier signal from the received signal and back restores the original source. In such process, a transmission noise has an effect on the received signal and therefore, a demodulated signal will be a source other than the original source.

A new communication technique known as the digital technique has been introduced, i.e. the communication technique has been developed into a digital communication system capable of receiving and transmitting sound, image, data, etc., rather than merely sound communication, by incorporating communication preformed by only the analog technique in the past, into the digital technique.

FIG. 2 is a block configuration view of a general digital communication system.

Herein, the original source means a digital signal represented by only 0 and 1. an original signal is converted into high efficient signal i.e. the signal in which the number of 0 and 1 is reduced, by a signal encoder and are sent to a transmission medium encoder. The transmission medium encoder converts the digital signal from the signal encoder into the digital signal with a constant rule, thereby making a signal system more strongly resistant against noise.

A transmitter finishes up its role by allowing the modulator to receive the signal and carry it on a carrier, and send it via the communication medium (for example, air).

A receiver receives the transmitted signal, a demodulator removes the carrier from it, a communication medium decoder restores the rule of the received signal as original, and a signal decoder back restores the reduced digital signal into the original state and outputs a final result.

Herein, the transmission encoder and decoder is to assure the reliability of communication; and, the signal encoder, the signal decoder, the modulator and the demodulator are to transmit and receive the signal at high speed.

The transmission medium encoder and decoder makes a regular signal system more strongly resistant against noise by preventing the distortion and loss of the signal from being generated during transmission, thereby assuring the reliability of communication; the signal encoder and decoder reduces the number of 0 and 1 required to represent the signal to enhance the speed of communication, i.e. the efficiency of communication; and, the modulator and the demodulator enhance the compressibility of the signal carried on the carrier to compress many 0 and 1 in a single signal.

Most general digital modulation/demodulation technique is Binary Phase Shift Keying (BPSK) technique, as indicated in FIG. 3. The technique changes the signals of 0 and 1 into the signals of 1 and −1 and thus, changes the phase of the carrier generally, a cosine wave) by 180 degree to restore the original value in the receive portion according to the change of the phase. However, in case of BPSK, because it carry only one signal for one wavelength, i.e. only one 0 or 1, its efficiency is low. Therefore, Quadrature Phase Shift Keying mode (QPSK) or Quadrature Amplitude Modulation mode (QAM) has been developed Such a Quadrature Amplitude Modulation mode can largely be divided into a diamond type and a square type according to constellation point and the invention is applied to only a square Quadrature Amplitude Modulation.

First, the QAM mode can carry many compressed signals for one wavelength, i.e. bits, by newly changing the amplitude of a given carrier, wherein a cosine wave and a sign wave are used as the carrier, and since the two waves are transmitted orthogonal to each other, there is no interference between them.

The amplitudes of the two waves are coupled with each other to make a plurality number of combinations and, if mathematically expressing them, they can be expressed into two numbers, which don't interfere with each other, i.e. a real number and an imaginary number. That is, in a complex number α+βi, changing the value of α have no effect on the value of β. For this reason, the cosine wave may be corresponded to α and the sine wave to β.

According to this, FIG. 4 represents 16 combinations placed in a complex plane as one example. QAM modulation/demodulation mode based on such 16 appointed points is referred to as 16-QAM.

As appreciated in FIG. 4, it represents 16 predefined points by the combination of amplitude changes of the cosine wave and the sine wave of such a real number portion and an imaginary number portion. Therefore, it is possible to compress four bits for one wavelength and to carry them. It is shown that the combination of 0 and 1 represented beneath the point of FIG. 4 is set up and distributed with a bunch of four bits compressed depending on position. That is, if the value of the real number portion is 3 and the value of the imaginary number portion is 1, the combination of corresponding bits, i.e. symbol is ‘0001’. In other words, if the amplitudes of the cosine wave and the sine wave are known, the combination of bits (symbol) that indicate the received signal can be found.

The modulator of QAM mode would send through a carrier the combination of the amplitudes of the sine wave and the cosine wave corresponding to the predefined 16 or more points (2²ⁿ, with n being an integer greater than 2), in the manner described above. Herein, in general, the signal corresponding to the real number portion is referred to as I-channel and the signal corresponding to the imaginary number portion is referred to as Q-channel. Further, the symbol set up in each point, i.e. the size of the combination of bits should be varied depending on the size of the constellation point according to each QAM. In other words, if the size of QAM is 2²ⁿ (n being an integer greater than 2), the number of bit set up in each point is 2n.

In general, the QAM demodulator is responsible for converting signal incoming the I-channel and the Q-channel, i.e. a received signal with α+β into a bunch of bits according to the predefined position as mentioned above, i.e. the constellation point. However, most of α+βi is not positioned in the predefined position, i.e. the constellation point due to the influence of noise interference on the received signal. For this reason, the demodulator should often restore the signal changed by the noise into the original signal.

Till now, such a process, i.e. the method of estimating the original signal would estimate, as the original signal, the signal having the shortest distance obtained by calculating the distance between the received α+βi and each constellation point, and output a value corresponding thereto as an output of the demodulator. FIG. 5 shows such a process. If a given signal is α+βi, the calculation of the distance between α+βi and perimetrical 4 points (1+1i, 1+3i, 3+1i, 3+3i) is as follows.
D₁=\sqrt{(α−1)²+(β−1)²}
D₂=\sqrt{(α−1)²+(β−3)²}
D₃=\sqrt{(α−3)²+(β−1)²}
D₄=\sqrt{(α−3)²+(β−3)²}

In this case, the shortest distance D₄ is 3+3i.

Therefore, the output value of the demodulator is ‘0011’. This QAM signal demodulation mode is referred to as a hard decision. However, this process may require a large amount of calculation to induce the degradation of the receiver ability. Therefore, an substantially used existing method has been adapted. The method is as follows. It compares whether the received signal is large or not, by comparing the values of the real number portion and the imaginary number portion with a reference value (2 of FIG. 5). Through this comparison process, it makes distinction every region as to whether the received value is close to which point. Consequently, in case the received value is included in a predetermined region of first quadrant, its approximation value is always ‘0011’. The most approximated original symbol can be found by making only this comparison, without having calculation for the actual distance. However, there has been any limitation in performing this approximation. It was just the approximation of symbol unit. According to the method described above, it is impossible to carry out the approximation of bit unit. In other words, because there is a bunch of four bits, it is disadvantage that it cannot approximate every bit.

### DISCLOSURE OF THE INVENTION

Therefore, the invention is to solve the problems involved in the prior art, and in a method of demodulating signal transmitted in QAM mode, an object of the invention is to provide a hard decision demodulation method that can enhance reliability and processing speed by demodulating the signal in bit unit.

To accomplish this object, in the hard decision demodulation method of QAM mode, the invention is characterized in that it includes determining in bit unit, a corresponding symbol value from a quadrature phase component value and an in-phase component value.

To carry out this process, a configuration of constellation point of QAM and a corresponding demodulation method as known in prior art will first be described as follows. The constellation point can largely be divided into three cases. Firstly, it is a distributed configuration as shown in FIG. 7 and FIG. 8. Secondly, it is a distributed configuration as shown in FIG. 10 and FIG. 11. Finally, the third configuration is not included in the scope of the claims.

The features of the configurations as shown in FIG. 7 and FIG. 8 can be summarized as follows. In case the size of QAM is 2²ⁿ, the number of bit set up in each point is 2n, wherein the first half of the number, i.e. the bits from the first to n are demodulated by one of received signals, i.e. either α or β, and the second half of the number, i.e. the bits from n+1 to 2n are demodulated by the other of the received signals. Also, the demodulation methods for the first half and the second half are the same. In other words, if the demodulation method of the first half is inserted with the value of the received signal corresponding to the second half, the result of the second half can be obtained. (Hereinafter, this configuration is conveniently referred to as ‘first type’)

The features of configurations as shown in FIG. 10 and FIG. 11 can be summarized as follows. In case the size of QAM is 2ⁿ, the number of bit set up in each point is 2n, and a method of demodulating bit every odd number is just met with a method of demodulating bit every next even number, wherein the value of the received signal for demodulating bit every odd number uses either α or β and the value of the received signal for demodulating bit every even number uses the other. In other words, for the first bit and the second bit, the demodulation methods are the same and only the values of the received signal used are different. (Hereinafter, this configuration is conveniently referred to as ‘second type’)

Based on the above description, an object of the invention is to faster and more accurately demodulate using new hard decision demodulation method corresponding to each configuration.

### BRIEF DESCRIPTION OF THE DRAWINGS

The other objects, features and advantages of the present invention will become more apparent by describing the preferred embodiment thereof with reference to the accompanying drawings, in which:

FIG. 1 is a view for describing modulation and demodulation process in a communication system.

FIG. 2 is a block configuration view for describing a general digital communication system.

FIG. 3 is a block configuration view for describing a general BPSK modulation method.

FIG. 4 is a view showing an example of constellation point in 16-QAM mode.

FIG. 5 is a view for describing a demodulation method of the 16-QAM mode shown in FIG. 4.

FIG. 6 is a view showing constellation point for describing a hard decision demodulation method according to the first embodiment of the invention

FIG. 7 and FIG. 8 are views for describing bit distribution in the constellation point shown in FIG. 6.

FIG. 9 is a view showing the constellation point for describing a hard decision demodulation method according to the second embodiment of the invention.

FIG. 10 and FIG. 11 are views for describing bit distribution in the constellation point shown in FIG. 9.

FIG. 12 is a functional block view showing a hard decision determination process according to the invention.

FIG. 13 is a view a hardware configuration for a hard decision demodulation of a first type of 64-QAM according to the invention

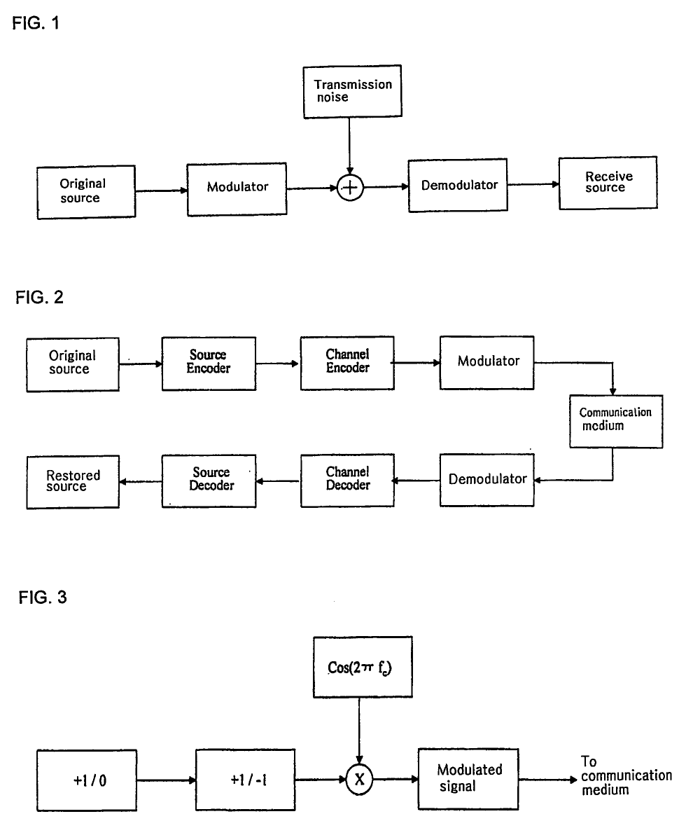

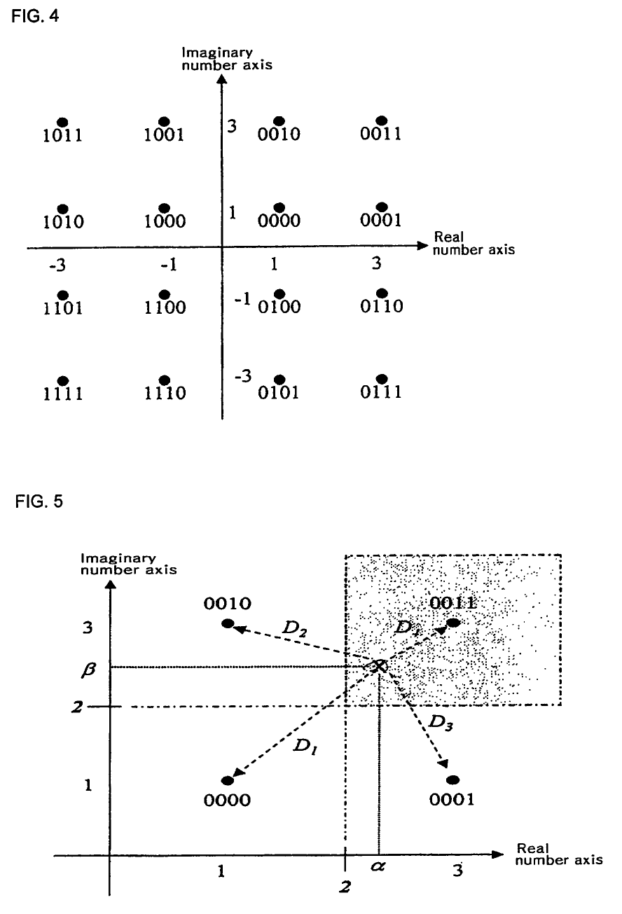

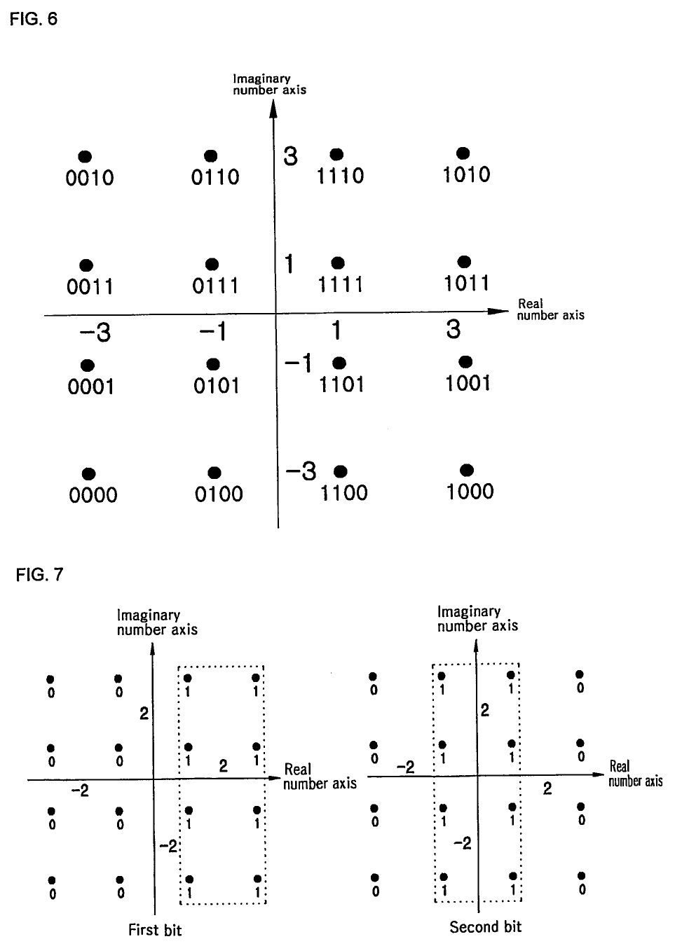

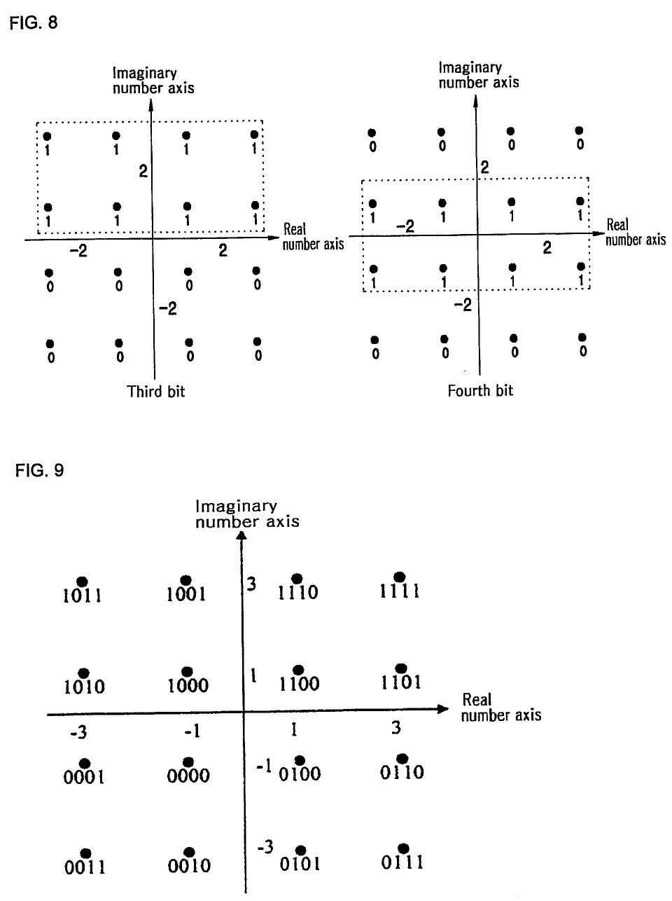

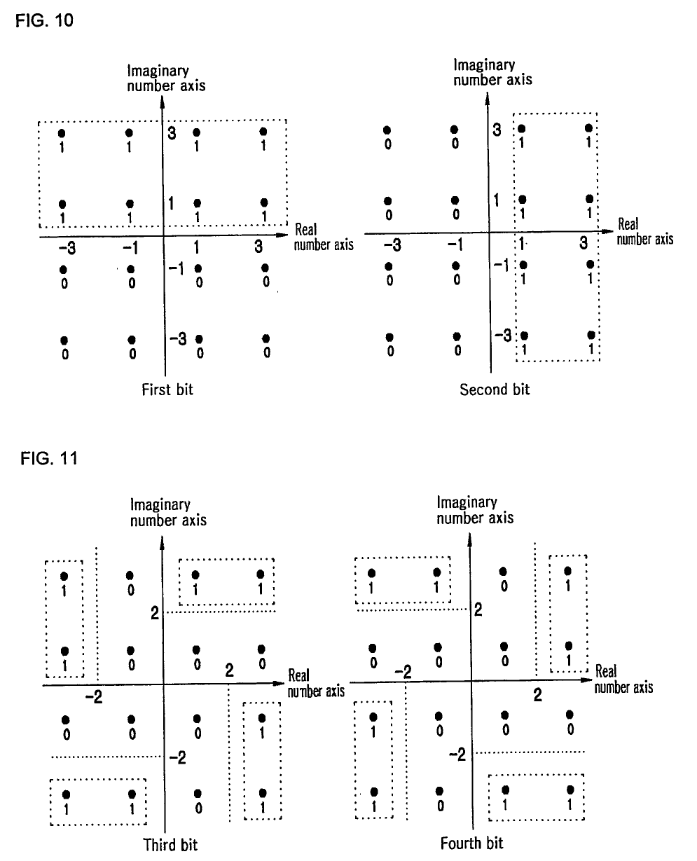

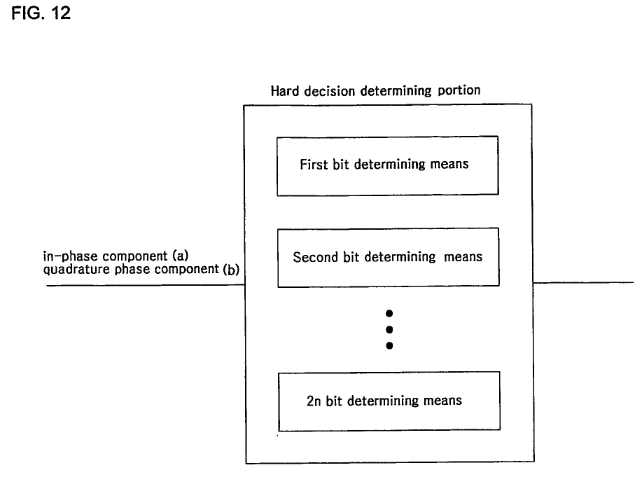

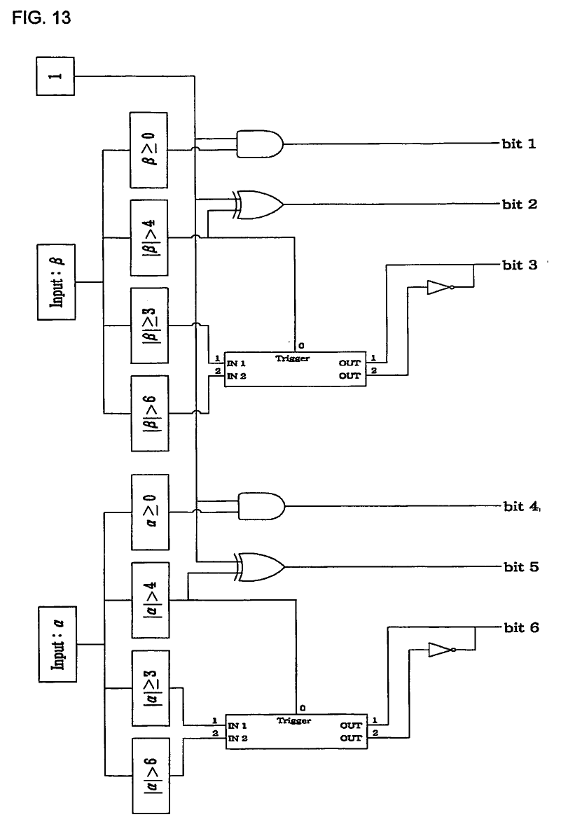

### BEST MODE FOR CARRYING OUT THE INVENTION

The invention relates to a hard decision demodulation method of demodulating signal transmitted in QAM mode, wherein the method can generally be applied irrespectively of the size of QAM. An array mode of QAM is a square type of array mode, such as 16QAM, 64-QAM, 256-QAM and 1024-QAM, and a diamond type of array mode, such as 32-QAM, 128-QAM and 512-QAM, as mentioned above.

The invention relates to the square type of QAM that has mainly been used in industry, and upon evaluating output signal on input signal, relates to a demodulation apparatus and method that can more accurately restore the signal as well as further enhance processing speed, by demodulating it in bit unit, not symbol unit. A newly developed QAM demodulation method will be described on a first type and a second type, respectively and an example of which will be shown through a first embodiment and a second embodiment. Further, if the input of the modulator is 1/0 or 1/−1 non-return-to-zero: NRZ), the configuration of the output is 1/0 or 1/−1 depending on the input signal of the modulator, i.e., if there are two values referred to a and b discriminated from each other, it is possible to output any configuration (for example, 1/0, 1/1, a/−a, a/b). The description below is based on 1/0.

Several values will first be explained, prior to description thereto. The size of QAM can be characterized by equation 1 and thus, the number of bit set up in each constellation point can be characterized by equation 2.
2²ⁿ-QAM, n=2,3,4, [Equation 1]
The number of bits established in each point=2n [Equation 2]

In case of the first type, in describing the feature of the first type, it would use either a value of a real number portion or a value of an imaginary number portion of the received signal to demodulate the combination of bits of first half as mentioned above, but the description below describes a demodulation method using β value for the first half and a value for the second half.

If β value is greater than or equal to 0, the first bit of the first type is ‘1’ as output value or else ‘0’ as output value.

A method for calculating the second bit can be expressed in equation 3.
If it is |β|/2ⁿ⁻¹≦1, then output is ‘1’ or else ‘0’. [Equation 3]

In other words, if |β|/2ⁿ⁻¹ value is less than or equal to 1, output is ‘1’ or else ‘0’.

The last bit of the first half from the third bit, i.e., the bits up to number n can be expressed in equation 4.
If it is 4m−3<|β|2^{n-k+1}≦4m−1(m=1, . . . ,2^{k-3}), then the output of bit number k(k is an integer greater than 3) is ‘1’ or else ‘0’. [Equation 4]

In other words, if the received β value satisfies 4m−3<|β|/2^{n-k+1}4m−1(m−1, . . . ,2^{k-3}), output is ‘1’ and if not, output is ‘0’.

The method for calculating the second half bits (i.e. bits from number n=1 to 2n) of the first type can be obtained by substituting α for β in a method obtaining the bit of the first half depending on the feature of the first type. In other words, the condition for substituting α for β (if β value is greater than or equal to 0, the output value is ‘1’ or else ‘0’) in a condition obtaining the first bit becomes a discrimination equation for the first bit, i.e., the n+1^{th} bit. If β is substituted for a in the equation 3 which is the condition for discriminating the second bit of the first half, then the second bit of the second half, i.e., the n+2^{th} bit can also be discriminated. The bits from n+3 to 2n can be discriminated by modifying the equation 4 as described previously. Then, the k value is used from 3 to n in order, instead from n+3 to 2n.

Also, to help the convenience of understandings for the second type, as discribed in the feature of the second type, α value is used for discriminating bit every odd number and β value is used for discriminating bit every even number.

If α value is less than 0, the first bit of the second type is ‘1’ or else ‘0’, as output value.

To discriminate the second bit, it would use bit every odd number just before bit to be intended to obtain based on the feature of the second type, i.e. the receive signal value used in the method for the first bit, i.e. a discrimination equation for substituting β for α (if β value is less than 0, the output vale is ‘1’ or else ‘0’).

To discriminate bits after the third bit in case of the second type, it should be considered to divide into two regions, since as shown in FIG. 11, in case of bits over the third bit of the second type, a discrimination equation must be applied dividing into two cases, i.e. α×β≧0 and α×β<0. First, in case α×β≧0, the discrimination equation of the third bit can be expressed in equation 5.
If it is |β|/2ⁿ⁻¹≧1, then output is ‘1’ or else ‘0’.

In case the fourth bit, the discrimination equation of the third bit depending on the feature of the second type, i.e. the discrimination equation for substituting β for α in equation 5 is used.

Under the condition of α×β≧0, the equation for discriminating bits over the fifth bit can be expressed in equation 6.

The discrimination equation of bit every odd number, i.e. 2q−1^{th} bit (q is an integer greater than 3) over the fifth bit is as follows.
If it is 4m−3<|β★/2^{n-q-1}≦4m=1(m=1, . . . ,2^{q-3}), then output is ‘1’or else ‘0’ [Equation 6]

The discrimination equation of bit every even number, i.e. 2q^{th} bit (q is an integer greater than 3) over the fifth bit is as follows.
If it is 4m−3|α|/2^{n-q+1}≦4m−1(m=1, . . . ,2^{q-3}), then output is ‘1’ or else ‘0’

In other words, in case bit number is over 5 and is an odd number bit, if it satisfies the discrimination equation 4m−3<|β|/2^{n-q+1}≦4m−1(m−1, . . . , 2^{q-3}), then output is ‘1’ and if not, output is ‘0’. Further, as appreciated in the feature of the second type and the equation 6, if β is substituted for a in the equation for discriminating bit every odd number, it becomes the equation for discriminating bit every even number.

Under the condition of α×β<0, the discrimination equation of bit over the third bit can be obtained by substituting a and β with each other in the discrimination equation under the condition of α×β≧0. This is also the feature of the second type.

Through this process, it is possible to perform a hard decision demodulation of a square type of QAM in bit unit using the received signal, i.e. the value of α+βi. In the method described above selecting the received signal and inserting it in a discrimination equation, it has randomly set the order of (α or β expressed in the equations to help understandings, but in practical application, more generally, it can switch their order according to the constellation point of QAM so that the order of the output value can also be switched from 1/0 to 0/1. In other words, as long as the discrimination equation is kept, the switch of two received signal values and the switch of two discriminated output values, which are inserted in the discrimination equation, can freely be selected according to the constellation point. The result is that the invention is used for various purposes to increase its meaning.

### First Embodiment

The first embodiment of the invention corresponds to the first type and is applied with the feature of the first type. In the first embodiment, an example includes the size of QAM being 1024, i.e. 1024-QAM.

Basically, QAM in two embodiments according to the invention is determined in following equation. Equation 1 determines the size of QAM and equation 2 indicates the number of bit set up in each point of constellation point depending on the size of QAM.
2²ⁿ-QAM, n=2, 3, 4, [Equation 1]
The number of bit set up in each point=2n [Equation 2]

Using these equations 1 and 2, there will be described in case when n=5, 2²*⁵-QAM=1024-QAM according to the equation 1 and the number of bit set up in each constellation point is 2×5=10 bits according the equation 2. Prior to applying the discrimination equation, it should be noted that if it know the discrimination equation for 5 bits of the first half, it can immediately know the discrimination equation for 5 bits of the second half.

Upon applying this, in case the output of the first bit is discriminated, if β value is greater than or equal to 0, the output value is ‘1’ or else ‘0’.

If the output value of the second bit is discriminated, it is expressed as follows using the equation 3.
If it is |β|/2⁴≦1, output is ‘1’ or else ‘0’.

If the output value of the third bit is discriminated, it is expressed as follows using the equation 4.
If it is 1<|β|/2³≦3 (m=1), output is ‘1’or else ‘0’.

If the output value of the fourth bit is discriminated, it is expressed as follows using the equation 4.
If it is 1<|β|/2²≦3 (m=1) or 5<|β|/2²≦7 (m=²), output is ‘1’or else ‘0’.

If the output value of the fifth bit is discriminated, it is expressed as follows using the equation 4.
If it is 1<|β|/2¹≦3 (m=1), 5<|β|/2¹≦7 (m=2), 9<|β|/2¹≦11 (m=3) or 13<|β|/2¹≦15 (m=4), output is ‘1’ or else ‘0’.

As described previously, the bits of the second half (i.e. bits from the sixth to the tenth) are discriminated by substituting α for β in a discrimination equation for bits from the first to the fifth.

### Second Embodiment

The second embodiment of the invention corresponds to the second type and is applied with the feature of the second type. In the second embodiment, an example includes the size of QAM being 1024, i.e. 1024-QAM.

In the second embodiment as in case of the first embodiment, Equation 1 determines the size of QAM and equation 2 indicates the number of bit set up in each point of constellation point depending on the size of QAM.
2²ⁿ-QAM, n=2, 3, 4, [Equation 1]
The number of bit set up in each point=2n [Equation 2]

Using these equations 1 and 2, there will be described in case when n=5, 2²*⁵-QAM=1024-QAM according to the equation 1 and the number of bit set up in each constellation point is 2×5=10 bits according the equation 2. Prior to applying the discrimination equation, it should be noted that the discrimination equation of bit every odd number is used in the discrimination equation of bit every next even number by substituting a and β with each other. Further, It will again be noted that in case of α×β>0 and α×β<0 in discriminating bit after the third bit, the discrimination equation is used substituting α and β with each other.

Upon applying this, if the first bit is first discriminated, if α value is less than 0, the output value is ‘1’ or else ‘0’.

The discrimination of the second bit is done by substituting β for α in the discrimination of the first bit depending on the feature of the second type, wherein if β value is less than 0, the output value is ‘1’ or else ‘0’.

The discrimination of bits from the third to the last tenth will be described dividing in cases of α×β≧0 and α×β≧0.

First, in case of α×β≧0, if the equation 5 is applied to discriminate the third bit, it is expressed as follows.
If it is |β|/2⁴≧1, output is ‘1’ or else ‘0’.

The fourth bit is an equation for substituting a for P in the discrimination equation of the third bit by applying the feature of the second type.

If the equation 6 is applied to discriminate the fifth bit, it is expressed as follows.
If it is 1<|β|/2³≦3 (m=1), output is ‘1’ or else ‘0’.

The sixth bit is an equation for substituting a for D in the discrimination equation of the fifth bit as described above.

If the equation 6 is applied to discriminate the seventh bit, it is expressed as follows.
If it is 1<|β|/2²≦3 (m=1) or 5<|β|/2≦7 (m=²), output is ‘1’ or else ‘0’.

The eighth bit is an equation for substituting α for β in the discrimination equation of the seventh bit as described above.

If the equation 6 is applied to discriminate the ninth bit, it is expressed as follows.
If it is 1<|β|/2¹≦3 (m=1), 5<|β|/2¹≦7 (m=2), 9<|β|/2¹≦11 (m=3) or 13<|β|/2¹≦15 (m=4), output is ‘1’ or else ‘0’.

The tenth bit is an equation for substituting α for β in the discrimination equation of the ninth bit as described above.

The discrimination equation of bits from the third to the tenth in case of α×β<0 can be obtained by substituting α into β or β into α with each other in case of the α×β≦0 depending on the feature of the second type.

### INDUSTRIAL APPLICABILITY

It is possible to develop a more useful demodulation technique by demodulating in bit unit, not in an existing symbol unit and to give a secondary function by independently processing each bit, according to a demodulation method of the invention. Further, the invention can be constituted of merely a comparison circuit without having arithmetic in a demodulation process, and therefore, it can enhance flexibility of actual configuration and processing speed.

1. In a hard decision demodulation method of QAM (Quadrature Amplitude Modulation) mode, characterized in that it includes determining in bit unit, a corresponding symbol value from a quadrature phase component value (β) and an in-phase component value (α) of a received signal.

2. The method as claimed in claim 1 characterized in that, the decision method of the first bit of the first type selects one of the received values, i.e. either α or β according to the configuration of constellation point, and determines that output is a or else b, if the value is greater than or equal to 0, wherein α is a receive value of I (a real number portion) channel, β is a receive value of Q (an imaginary number portion) channel, and a and b is any number discriminated from each other.

3. The method as claimed in claim 1 characterized in that, the decision method of the second bit selects one of the received values, i.e. either α or β, and determines that output is a or else b, if |Ω|/2ⁿ⁻¹ value is less than or equal to 0, wherein a and b is any number discriminated from each other, n is the size of QAM, i.e. a variable determining 2²ⁿ and Ω is the received value selected.

4. The method as claimed in claim 1 characterized in that, the decision method of bit over the third bit of the first and less than n^{th} bit selects one of the received values, i.e. either α or β, and is determined by equation 4 below,
[Equation 4]
If it is 4m−3<|Ω|2^{n-k+1}≦4m−1(m=1, . . . ,2^{k-3}), then the output of bit number k(k is an integer greater than 3) is ‘a’ or else ‘b’, wherein a and b is any number discriminated from each other, n is the size of QAM, i.e. a variable determining 2²ⁿ and Ω is the received value selected.

5. The method as claimed in claim 1 characterized in that, the determination of bit from n+1^{th} to 2n^{th} is the same with the method of determining bit from the first to n^{th} corresponding thereto, but is determined by substituting non-selected one of the received values, i.e. either α or β for an input value of the equation.

6. The method as claimed in claim 1 characterized in that the decision method of the first bit of the second type selects one of the received values, i.e. either α or β according to the configuration of the constellation point, and determines that output is a or else b, if the value is less than 0, wherein α is a receive value of I (a real number portion) channel, β is a receive value of Q (an imaginary number portion) channel, and a and b is any number discriminated from each other.

7. The method as claimed in claim 1 characterized in that, the decision method of the second bit uses the received value non-selected in the decision method of the first bit of the second type and determines that output is a or else b, if the value is less than 0, wherein a and b is any number discriminated from each other.

8. The method as claimed in claim 1 characterized in that, the decision method of the third bit of the second type selects one of the received values, i.e. either α or β according to the configuration of the constellation point and then, determines that output is a or else b, if the result of α×β is greater than 0 but |Ω|/2ⁿ⁻¹ is greater than or equal to 1 or the result of α×β is less than 0 but |φ|/2ⁿ⁻¹ is greater than or equal to 1, wherein a and b is any number discriminated from each other, n is the size of QAM, i.e. a variable determining 2²ⁿ, α is a receive value of I (a real number portion) channel, β is a receive value of Q (an imaginary number portion) channel, Ω is the received value selected and Ψ is the received value non-selected.

9. The method as claimed in claim 1 characterized in that, the decision method of the fourth bit of the second type is determined by an equation for switching (determining that output is a or else b, if the result of α×β is greater than 0 but |φ|/2ⁿ⁻¹ is greater than or equal to 1 or the result of α×β is less than 0 but |Ω|/2ⁿ⁻¹ is greater than or equal to 1) the position of two received values in the decision method of third bit, wherein a and b is any number discriminated from each other, n is the size of QAM, i.e. a variable determining 2²ⁿ, α is a receive value of I (a real number portion) channel, β is a receive value of Q (an imaginary number portion) channel, Ω is the received value selected and Ψ is the received value non-selected.

10. The method as claimed in claim 1, the decision method of odd number bit over the fifth selects one of the received values, i.e. either α or β according to the configuration of the constellation point and is determined by equation 7 below,
[Equation 7]
The discrimination equation of bit every odd number, i.e. 2q-1 bit (q is an integer greater than 3) over the fifth bit is as follows:
If it is α*β≧0 and 4m−3<|Ω|/2^{n-q+1}23 4m−1(m−1, . . . ,2^{q-3}), or α*β<0 and 4m−3|Ψ|/2^{n-q+1}≦4m−1(m=1, . . . ,2^{q-3}), output is ‘a’ or else ‘0’, wherein α is an input value of I channel, β is an input value of Q channel, n is the size of QAM, i.e. a variable determining 2²ⁿ, Ω is the received value selected and v is the received value non-selected.

11. The method as claimed in claim 1 characterized in that, the decision method of even number bit over the fifth bit selects one of the received values, either α or β according to the configuration of the constellation point and is determined by equation 8 below,
[Equation 8]
The discrimination equation of bit every even number, i.e. 2q^{th} bit (q is an integer greater than 3) over the fifth bit is as follows:
If it is α*β≧0 and 4m−3<|Ψ|/2^{n-q+1}≦4m−1(m−1, . . . ,2^{q-3}), or α*β<0 and 4m−3<|Ω|/2^{n-q+1}≦4 m−1(m=1, . . . ,2^{n-q-3}), output is ‘a’ or else ‘0’, wherein α is an input value of I channel, β is an input value of Q channel, n is the size of QAM, i.e. a variable determining 2²ⁿ, Ω is the received value selected and Ψ is the received value non-selected.

12. In a hard decision demodulation apparatus of QAM (Quadrature Amplitude Modulation) mode, characterized in that it includes a hard decision determining portion of determining in bit unit, a corresponding symbol value from a quadrature phase component value and an in-phase component value of a received signal.
